(19) United States
(12) Patent Application Publication
(10) Pub. No.: US 2014/0284550 A1
(43) Pub. Date: Sep. 25, 2014

(54) LIGHT-EMITTING DEVICE

(71) Applicant: STANLEY ELECTRIC CO., LTD., Tokyo (JP)

(72) Inventor: Mitsuyasu KUMAGAI, Yokohama-shi (JP)

(73) Assignee: STANLEY ELECTRIC CO., LTD., Tokyo (JP)

(21) Appl. No.: 14/221,243

(22) Filed: Mar. 20, 2014

(30) Foreign Application Priority Data
Mar. 21, 2013 (JP) 2013-058370

(51) Int. Cl. H01L 33/06; H01L 33/00; H01L 33/32

(52) U.S. Cl. CPC H01L 33/06; H01L 33/32; H01L 33/0025
USPC 257/13

(57) ABSTRACT

A light-emitting device including a GaN-based semiconductor has a structure in which sequentially deposited are an n-type semiconductor layer, a superlattice structure layer including at least one InGaN superlattice layer, an active layer, an AlGaN-based semiconductor layer, and a p-type semiconductor layer. A concavo-convex structure is formed on the interface of the AlGaN-based semiconductor layer with the p-type semiconductor layer. The active layer is an InGaN layer or an InGaN quantum well layer. The InGaN superlattice layer has an In composition that is greater than that of the active layer.

### BACKGROUND OF THE INVENTION

1. Field of the Invention

The present invention relates to light-emitting devices, and more particularly to a light-emitting device of a gallium nitride (GaN)-based semiconductor.

2. Description of the Related Art

The semiconductor light-emitting device such as the light-emitting diode (LED) is fabricated typically by forming, on a growth substrate, a semiconductor structure layer that is made up of an n-type semiconductor layer, an active layer (light-emitting layer), and a p-type semiconductor layer, and by forming an n-electrode and a p-electrode on the semiconductor structure layer.

Disclosed in Japanese Patent Application Laid-Open No. 2007-88481 is a nitride semiconductor device which has a current diffusion layer between an n-type nitride semiconductor layer and an active layer and in which a p-type nitride semiconductor layer has a structure made up of a p-type AlGaN layer and a p-type GaN layer.

### SUMMARY OF THE INVENTION

For example, a light-emitting device made of a nitride-based semiconductor may include an n-GaN layer as the n-type semiconductor layer, an undoped InGaN layer as the active layer, and a p-GaN layer as the p-type semiconductor layer.

Meanwhile, in a technique for supplying electrons to the entire active layer (the InGaN active layer) from the n-GaN layer upon application of a current, it is known to form an InGaN layer (current diffusion layer) between the n-GaN layer and the InGaN active layer.

Furthermore, in a technique for preventing overflow of so-called hot electrons or electrons that leak to the p-GaN layer across the active layer, it is known, for example, to form an AlGaN layer (electron block layer) between the active layer and the p-GaN layer.

For example, as disclosed in Japanese Patent Application Laid-Open No. 2007-88481, the current diffusion layer and the electron block layer may be formed between the n-GaN layer and the active layer and between the active layer and the p-GaN layer, respectively. In this case, it is possible to achieve the aforementioned effects (the current diffusion effect and the effect of suppressing the electron overflow, respectively).

On the other hand, there still exists a problem with the conventional techniques in that an increase in the number of interfaces for forming a heterojunction, i.e., junction that occurs between two layers of crystalline semiconductors having different crystalline lattice constants, may cause deterioration in the crystallinity of the entire semiconductor structure layer. For example, a crystalline strain caused by the difference in lattice constant may lead to the occurrence of a piezoelectric field and degradation in the probability of an electron-hole recombination. Thus, this may lead to degradation in emission efficiency. Furthermore, the deterioration in crystallinity may bring about degradation in the reliability of the device as another problem.

It has therefore been contrived in view of the above circumstances, and an object of the present invention is to provide a light-emitting device which prevents the strain of the semiconductor structure layer, in particular, the strain of the active layer, thereby achieving high emission efficiency and high reliability.

A light-emitting device according to the present invention is made of a GaN-based semiconductor and has a structure in which sequentially deposited are, an n-type semiconductor layer, a superlattice structure layer including at least one InGaN superlattice layer, an active layer, an AlGaN-based semiconductor layer, and a p-type semiconductor layer. The light-emitting device is also configured such that a concavo-convex structure is formed on an interface of the AlGaN-based semiconductor layer with the p-type semiconductor layer; the active layer is an InGaN layer or an InGaN quantum well layer; and the InGaN superlattice layer has an In composition greater than an In composition of the active layer.

### BRIEF DESCRIPTION OF THE DRAWINGS

The aforementioned aspects and other features of the present invention are explained in the following description, taken in connection with the accompanying drawing figures wherein:

FIGS. 1A and 1B are an explanatory view illustrating the structure of a semiconductor light-emitting device according to a first example;

FIGS. 2A and 2B are an explanatory view illustrating a preferred range of an In composition (x) of a superlattice structure layer and an Al composition (y) of an AlGaN-based semiconductor layer; and

FIG. 3A is a band diagram schematically illustrating a semiconductor structure layer of the semiconductor light-emitting device according to the first example, and FIG. 3B is an explanatory view schematically illustrating the strain of a semiconductor structure layer according to the first example and a comparative example.

### DETAILED DESCRIPTION OF THE INVENTION

The present invention was developed by focusing attention on the fact that the crystalline strain of a semiconductor structure layer, in particular, of an active layer can be prevented by controlling the composition of a current diffusion layer provided between an n-type semiconductor layer and the active layer and the composition of an electron block layer provided between the active layer and a p-type semiconductor layer. As a result, derived was the range of the In composition of the current diffusion layer and the Al composition of the electron block layer in which the crystalline strain is prevented and high emission efficiency is achieved.

Furthermore, the inventor has found that the structure of the electron block layer has an effect on the degree to which the crystalline strain is prevented. More specifically, it was found that the AlGaN layer having a concavo-convex structure on the surface thereof has the effect of reducing the strain of the semiconductor structure layer.

Now, the structure of the semiconductor light-emitting device according to an example of the present invention will be specifically described below.

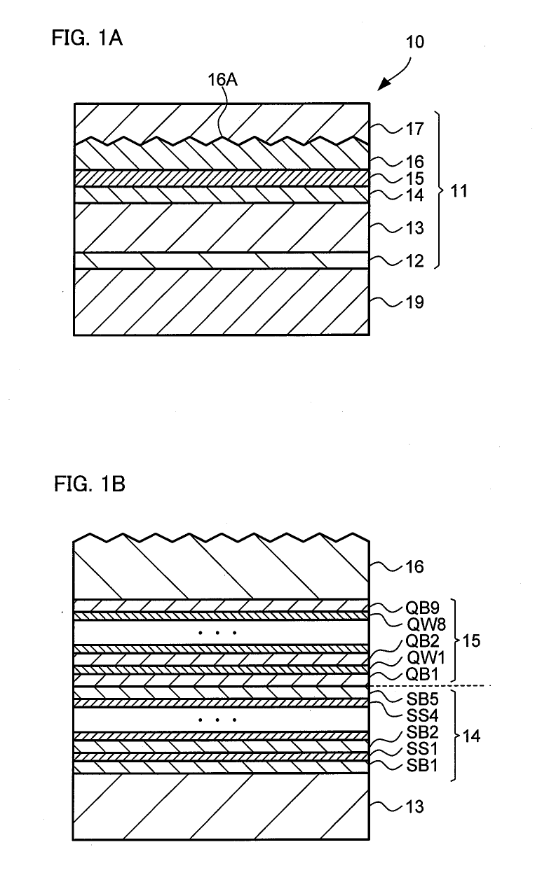

FIG. 1A is a cross-sectional view illustrating the structure of the semiconductor light-emitting device 10 according to a first example of the present invention. The semiconductor light-emitting device 10 is configured such that a semiconductor structure layer 11 is formed on a growth substrate 19. The semiconductor structure layer 11 has a structure in which a buffer layer 12, an n-type semiconductor layer 13, a superlattice structure layer 14, an active layer 15, an AlGaN-based semiconductor layer 16, and a p-type semiconductor layer 17 are sequentially deposited in that order from the side of the growth substrate 19.

Now, a description will be made to the case where employed are a sapphire substrate 19 as the growth substrate, a GaN layer 12 as the buffer layer, an n-GaN layer 13 as the n-type semiconductor layer, a superlattice structure (SL) layer 14 made up of InGaN superlattice layers and GaN layers as the superlattice structure layer, an active layer 15 having a multi quantum well structure made up of InGaN well layers and GaN barrier layers as the active layer, a p-AlGaN layer 16 as the AlGaN-based semiconductor, and a p-GaN layer 17 as the p-type semiconductor layer.

In this example, grown by the Metal Organic Chemical Vapor Deposition (MOCVD) method on the sapphire substrate 19 having the C surface as a crystal growth surface are the GaN layer 12 (1 μm in thickness), the n-GaN layer 13 (4 μm in thickness, Si dopant, and a carrier concentration of 5×10¹⁸ cm⁻³), the superlattice structure layer 14 (undoped, 4 nm in the thickness of each InGaN superlattice layer, 5 nm in the thickness of each GaN layer, and four layers in the InGaN superlattice layer), the active layer 15 (undoped, 4 nm in the thickness of each InGaN well layer, 5 nm in the thickness of each GaN barrier layer, and eight layers in the InGaN well layer), the p-AlGaN layer 16 (15 nm in thickness, Mg dopant, and a carrier concentration of 2.2×10¹⁸ cm⁻³), and the p-GaN layer 17 (100 nm in thickness, Mg dopant, a carrier concentration of 4×10¹⁷ cm⁻³). Furthermore, the growth conditions were controlled so that the InGaN well layer of the active layer 15 had a composition of In_{Z}Ga_{1-z}N (0.25≦z≦0.30). The superlattice structure layer 14 was formed so that the In composition of the InGaN superlattice layer was greater than the In composition (z) of the active layer 15.

FIG. 1B is an explanatory cross-sectional view illustrating the details of the superlattice structure layer 14 and the active layer 15. As shown in FIG. 1B, the superlattice structure layer 14 has four InGaN superlattice layers (SS1 to SS4), each layer being provided between each of the GaN layers (SB1 to SB5). Furthermore, the active layer 15 has eight InGaN well layers (QW1 to QW8), each layer being provided between each of the GaN barrier layers (QB1 to QB9).

More specifically, sequentially deposited on the n-GaN layer 13 as the superlattice structure layer 14 are the GaN layer SB1, the InGaN superlattice layer SS1, the GaN layer SB2, the InGaN superlattice layer SS2, . . . , the InGaN superlattice layer SS4, and the GaN layer SB5. Sequentially deposited as the active layer 15 on the GaN layer SB5 of the superlattice structure layer 14 are the GaN barrier layer QB1, the InGaN well layer QW1, the GaN barrier layer QB2, . . . , the GaN barrier layer QB8, the InGaN well layer QW8, and the GaN barrier layer QB9. The AlGaN-based semiconductor layer 16 is formed on top of the GaN barrier layer QB9 of the active layer 15.

Note that hereinafter, any of the InGaN superlattice layers SS1 to SS4 in the superlattice structure layer 14 may also be simply referred to as the InGaN superlattice layer SS. In the same manner, any of the GaN layers SB1 to SB5 in the superlattice structure layer 14, and any of the InGaN well layers QW1 to QW8 and the GaN barrier layers QB1 to QB9 in the active layer may also be referred to as the GaN layer SB, the InGaN well layer QW, and the GaN barrier layer QB, respectively.

[Structure of the p-AlGaN Layer 16]

The p-AlGaN layer (AlGaN-based semiconductor layer) 16 has a concavo-convex structure 16A on the surface thereof toward the p-GaN layer 17 (on the interface with the p-GaN layer 17). The concavo-convex structure 16A can be formed by controlling the growth conditions of the p-AlGaN layer 16. More specifically, the concavo-convex structure 16A can be formed by controlling the growth temperature, the V/III ratio (the supply ratio of the group V material to the group III material), and the percentage of hydrogen in a carrier gas when the p-AlGaN layer 16 is grown.

In this example, the growth temperature was set to about 1000° C. (which is lower than a typical growth temperature at which AlGaN is grown), and the V/III ratio was set to 50,000 (which is greater than a typical V/III ratio). Furthermore, the flow ratio (F) of hydrogen in the carrier gas can be expressed by Equation F=H₂/(H₂+IG), where IG is an inert gas (for example, N₂, Ar, and He). In addition, F=0.23 in this example.

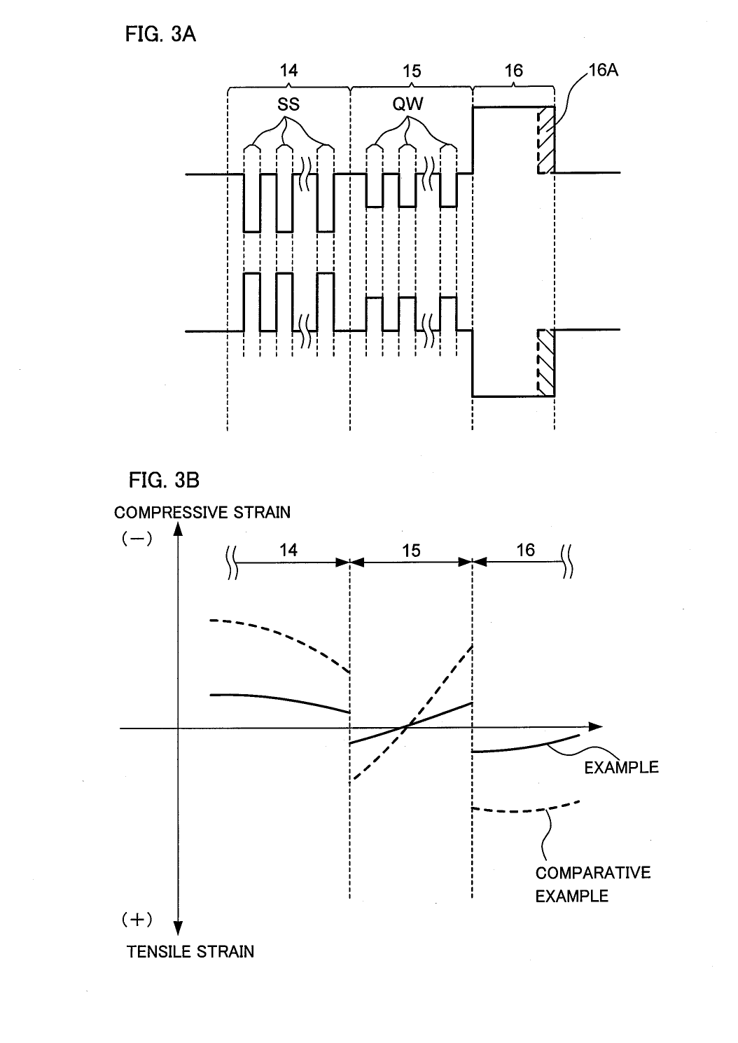

The p-AlGaN layer 16 has the concavo-convex structure 16A on the interface with the p-GaN layer 17, so that when compared with a p-AlGaN layer provided with no concavo-convex structure, it is possible to reduce the strain of the superlattice structure layer 14 and the p-AlGaN layer 16 between which the active layer 15 is sandwiched. It is also possible to prevent the strain of the crystal in the vicinity of the concavo-convex structure 16A portion, that is, the interface between the p-AlGaN layer 16 and the p-GaN layer 17. Thus, the p-AlGaN layer 16 having the concavo-convex structure 16A makes it possible to prevent the strain of the semiconductor structure layer 11. This effect will be discussed later with reference to FIGS. 3A and 3B.

The concavo-convex structure 16A formed on the interface between the p-AlGaN layer 16 and the p-GaN layer 17 is made up of superfine irregularities, which have a depth of about 5 nm or less. Furthermore, the concavo-convex structure 16A portion has a slightly higher Al composition (about 13%) than the other p-AlGaN layer 16 portion (the p-AlGaN layer 16 portion toward the active layer 15 rather than the concavo-convex structure 16A portion). For example, when the p-AlGaN layer 16 portion other than the concavo-convex structure 16A has an Al composition of 21%, the concavo-convex structure 16A portion has an Al composition of 22% to 24%.

Furthermore, the concavo-convex structure 16A includes, on the surfaces thereof, fine crystalline facets which have various plane orientations other than the growth plane (i.e., the C plane) of the p-AlGaN layer 16. The p-AlGaN layer 16 having the concavo-convex structure 16A causes the p-GaN layer 17 to be grown on the various crystalline facets. This is understood to have the effects of preventing a lattice mismatch and in turn preventing the strain of the entire semiconductor structure layer.

Note that the shape and the thickness (depth) of the irregularities of the concavo-convex structure 16A can be controlled to some extent by controlling growth conditions. By taking into account the morphology of the p-GaN layer 17 formed on the concavo-convex structure 16A, the depth of the irregularities may be 1 to 5 nm, and preferably 2 to 3 nm.

Note that as with a conventional technique, the p-AlGaN layer 16 functions as an electron block layer (for preventing electrons from overflowing out of the active layer.) Furthermore, it has been confirmed that the concavo-convex structure 16A of the p-AlGaN layer 16 serves to prevent the interdiffusion of a dopant of the p-AlGaN layer 16 and the p-GaN layer 17 or Mg between the p-AlGaN layer 16 and the p-GaN layer 17.

[In Composition (x) and Al Composition (y)]

Now, a description will be made to the relation between the In composition (x) of the superlattice structure layer 14 and the Al composition (y) of the p-AlGaN layer 16. In the descriptions below, the In composition of the InGaN superlattice layer SS of the superlattice structure layer 14 may be simply referred to also as the In composition (x), and the Al composition of the p-AlGaN layer 16 simply as the Al composition (y).

First, the In composition (x) of the InGaN superlattice layer SS of the superlattice structure layer 14 and the Al composition (y) of the p-AlGaN layer 16 have the relation which meets that 0.06≦(x×y)≦0.09 (hereinafter referred to as Equation 1) (where (x×y) is the value of the product of the value of the In composition (x) and the value of the Al composition (y).) That is, the InGaN superlattice layer SS of the superlattice structure layer 14 and the p-AlGaN layer 16 have elemental compositions that satisfies the compositional formula that meets Equation 1.

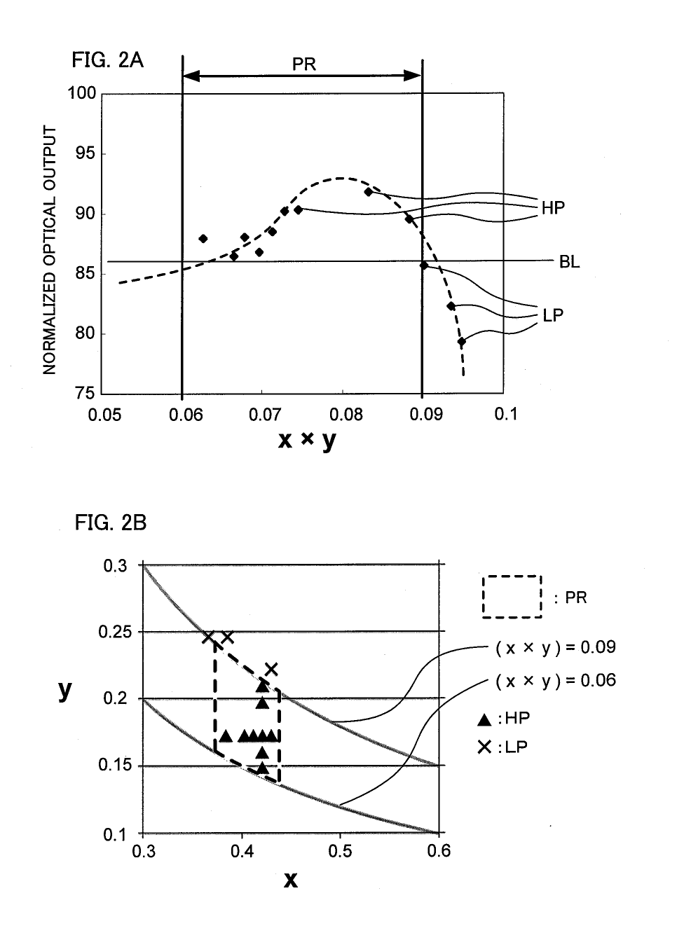

FIG. 2A is a graph showing the measurement results indicative of the optical output from the semiconductor light-emitting device 10 according to this example. FIG. 2A shows the electro luminescence (EL) measurement results of a plurality of semiconductor light-emitting devices which were provided with superlattice structure layers and p-AlGaN layers that had different (x×y) values. The horizontal axis of the figure represents the value of (x×y), and the vertical axis represents the normalized optical output. The broken line in the figure is a curve fitting that indicates the correlation between the value of (x×y) and the optical output.

From the measurement results shown in FIG. 2A, it is seen that the semiconductor light-emitting devices provide optical output that increases up to near an (x×y) value of about 0.08 but abruptly decreases beyond 0.09. It is thus seen that those devices having an (x×y) value of 0.09 or less could provide high optical output. It is also seen that those devices having (x×y) values within the range (PR) of 0.06 to 0.09 (the points above the threshold value BL in the figure) provide further increased optical output. Thus, the (x×y) values of the semiconductor light-emitting devices preferably meet (Equation 1). In the descriptions below, for convenience of explanation, those measurement points having (x×y) values above 0.09 in the figure (three points in the figure) may be referred to as a low optical output point LP. On the other hand, those measurement points having (x×y) values of 0.09 or less may be referred to as a high optical output point HP.

Now, a description will be made to each of the In composition (x) of the InGaN superlattice layer SS of the superlattice structure layer 14 and the Al composition (y) of the p-AlGaN layer. The superlattice structure layer 14 has the InGaN superlattice layer SS that has a composition of InₓGa₁₋ₓN (0.37≦x≦0.45). On the other hand, the p-AlGaN layer 16 preferably has a composition of Al_{y}Ga_{1-y}N (0.1≦y≦0.24).

FIG. 2B is a view illustrating the preferred range PR of the In composition (x) contained in the InGaN superlattice layer SS of the superlattice structure layer 14 and the Al composition (y) contained in the p-AlGaN layer 16. The horizontal axis of the figure represents the In composition (x), and the vertical axis represents the Al composition (y). The upper curve in the figure represents a group of points that meet Equation, (x×y)=0.09, while the lower curve represents a group of points that meet Equation, (x×y)=0.06. Those points indicated by the triangle in the figure correspond to the high optical output points HP of FIG. 2A. On the other hand, those points indicated by the “x” mark in the figure correspond to the low optical output points LP of FIG. 2A.

Form FIG. 2A, it can be seen that the condition is for the (x×y) values to satisfy (Equation 1), that is, to take on the values between the upper curve and the lower curve of FIG. 2B. However, each of the In composition (x) and the Al composition (y) has a preferred range that results from the consideration of the function of the superlattice structure layer 14 and the AlGaN-based semiconductor layer 16.

The In composition (x) of the InGaN superlattice layer SS of the superlattice structure layer 14 may take on larger values with an increased possibility of lattice mismatch and smaller values with an increased possibility of impairing the current diffusion function. In consideration of this fact, the superlattice structure layer 14 preferably has the InGaN superlattice layer SS with a composition of InₓGa₁₋ₓN (0.37≦x≦0.45).

The Al composition (y) of the AlGaN-based semiconductor layer 16 may take on larger values with an increased possibility of lattice mismatch and smaller values with an increased possibility of impairing the electron block function. In consideration of this fact, the AlGaN-based semiconductor layer 16 preferably has a composition of Al_{y}Ga_{1-y}N (0.14≦y≦0.24).

By taking these conditions into account, the In composition (x) and the Al composition (y) that are included in the region (the preferred range PR) surrounded by the broken lines of FIG. 2B can be selected, thereby making full use of the capabilities of each layer of the semiconductor structure layer and preventing the strain of the semiconductor structure layer.

Thus, the In composition (x) of the InGaN superlattice layer SS of the superlattice structure layer 14 and the Al composition (y) of the AlGaN-based semiconductor layer (p-AlGaN layer) 16 preferably satisfy the relation that 0.06≦(x×y)≦0.09, while more preferably, the In composition (x) lies within the range of 0.37≦x≦0.45 and the Al composition (y) within the range of 0.14≦y≦0.24. Note that examples of the In composition (x) and the Al composition (y) in the preferred range PR may include (x, y)=(0.21, 0.42) and (0.38, 0.18).

FIG. 3A shows a band diagram schematically illustrating a semiconductor structure layer 11 of the semiconductor light-emitting device 10. For explanation purposes, the concavo-convex structure 16A of the p-AlGaN layer 16 is hatched. Furthermore, the superlattice structure layer 14 and the active layer 15 are illustrated with the intermediate portions in each layer omitted.

The InGaN superlattice layer SS of the superlattice structure layer 14 and the InGaN well layer QW of the active layer 15 has a band gap that is less than that of the GaN layer (such as the n-GaN layer or the p-GaN layer which has a GaN composition.) Furthermore, the In composition of the InGaN superlattice layer SS is greater than the In composition of the InGaN well layer QW. Thus, electrons are diffused from the n-GaN layer into the superlattice structure layer 14 and supplied to the entire active layer 15, thereby allowing light to be emitted from the active layer 15.

The p-AlGaN layer 16 has a band gap greater than that of the GaN layer. Thus, the electrons supplied to the active layer 15 will remain in the active layer 15 without moving into the p-GaN layer (not shown). Furthermore, the p-AlGaN layer 16 which has the concavo-convex structure 16A prevents diffusion of a p-type dopant or Mg. Thus, a large portion of the supplied electrons can contribute to emission of light.

FIG. 3B is an explanatory view schematically illustrating the strain of the superlattice structure layer 14, the active layer 15 and the p-AlGaN layer 16. Firstly, a description will be made to the strain of each layer. As explained by using FIG. 3A, the superlattice structure layer 14 and the p-AlGaN layer 16 can make full use of each of the capabilities thereof (such as the current diffusion function, the electron block function, and the dopant diffusion prevention function). However, the superlattice structure layer 14 and the p-AlGaN layer 16 may have strain because of the lattice constants different from that of the GaN layer (such as the n-GaN layer and the p-GaN layer).

More specifically, the superlattice structure layer 14 having the InGaN superlattice layer SS with part of Ga substituted by In may have a compressive strain in the crystal thereof. On the other hand, the p-AlGaN layer 16 with part of Ga substituted by Al may have a tensile strain in the crystal thereof.

The strain of the superlattice structure layer 14 and the p-AlGaN layer 16 imparts stress on the active layer 15, causing degradation in the characteristics such as the optical output. Furthermore, this may also have a detrimental effect on the reliability of the light-emitting device.

FIG. 3B is a schematic view for describing in a simplified manner the relation in strain between the superlattice structure layer 14, the active layer 15, and the p-AlGaN layer 16. FIG. 3B schematically shows the strain of each of the superlattice structure layer 14, the active layer 15, and the p-AlGaN layer 16.

FIG. 3B schematically illustrates the strain of the semiconductor structure layer in the case (the example) where the semiconductor structure layer includes the p-AlGaN layer 16 having the concavo-convex structure 16A and the case (a comparative example) where the semiconductor structure layer includes a flat AlGaN layer that does not have the concavo-convex structure 16A (by the solid line and the broken line, respectively). The horizontal axis of the figure represents the direction of lamination and the vertical axis of the figure schematically represents the magnitude of the strain. The upper part of the figure shows greater compressive strain and the lower part of the figure shows greater tensile strain.

As can be seen from FIG. 3B, in the example (solid line), the strain of each of the superlattice structure layer 14 and the p-AlGaN layer 16 has been reduced when compared with the comparative example (broken line). Thus, the strain of the active layer according to this example is less than the strain of the active layer according to the comparative example. Furthermore, the strain of the concavo-convex structure 16A portion, that is, near the interface between the p-AlGaN layer 16 and the p-GaN layer 17 has been reduced by the concavo-convex structure 16A. Thus, the strain of the entire semiconductor structure layer is reduced, thereby allowing for improving the characteristics of the device such as the reliability of the crystal. Furthermore, the emission efficiency of the light-emitting device is improved.

As described above, the semiconductor light-emitting device according to this example has the superlattice structure layer that includes the InGaN superlattice layer having an In composition higher than the In composition of the InGaN well layer of the active layer. The semiconductor light-emitting device also has the AlGaN-based semiconductor layer that includes the concavo-convex structure on the interface with the p-type semiconductor layer. It is thus possible to provide a semiconductor light-emitting device having a high emission efficiency and including the semiconductor structure layer which is capable of supplying electrons to the entire active layer with high efficiency and which has prevented crystalline strain.

Furthermore, the InGaN superlattice layer is an InₓGa₁₋ₓN layer (x: In composition), and the AlGaN-based semiconductor layer is an Al_{y}Ga_{1-y}N layer (y: Al composition), in which the In composition (x) and the Al composition (y) meet the relations that 0.37≦x≦0.45, 0.14≦y≦0.24, and x×y≦0.09 (preferably, 0.06≦x×y≦0.09). Thus, it is possible to prevent the strain of the semiconductor structure layer, and particularly, the strain of the active layer.

In addition to the aforementioned semiconductor device in which the active layer has the multi quantum well structure, the active layer may also have a single quantum well structure or single layer structure. For example, the active layer may also be an InGaN layer or an InGaN quantum well layer. Furthermore, the composition and thickness of the InGaN well layer and the GaN barrier layer of the active layer and the number of layers of the InGaN well layer can be controlled, as appropriate, by taking into account the light emission wavelength or the like. Furthermore, the thickness and dopant concentration of the n-type semiconductor layer, the AlGaN-based semiconductor layer, and the p-type semiconductor layer can be controlled as appropriate.

Furthermore, in addition to the aforementioned semiconductor device in which the superlattice structure layer has the InGaN superlattice layers of four layers, the superlattice structure layer may only have to include at least one InGaN superlattice layer. For example, the superlattice structure layer may also have a structure in which one InGaN superlattice layer is sandwiched by two GaN barrier layers. Furthermore, in the aforementioned semiconductor device structure, the thickness of the InGaN superlattice layer can be controlled, as appropriate, within the range of 2 to 10 nm in consideration of the current diffusion effect and the strain prevention effect.

Still further, in addition to the aforementioned semiconductor device in which the concavo-convex structure can be formed by controlling the growth conditions of the AlGaN layer, other than the aforementioned semiconductor device structure, the concavo-convex structure may also be formed on a surface of the AlGaN-based semiconductor layer by a known surface roughening technique that employs etching or sputtering. Since the AlGaN-based semiconductor layer may only have to be an AlGaN layer that has a concavo-convex structure on a surface, for example, a flat AlGaN layer may be first formed as the AlGaN-based semiconductor layer on the active layer, and then the growth conditions may be varied to form the AlGaN layer having a concavo-convex structure.

It is understood that the foregoing description and accompanying drawings set forth the preferred embodiments of the present invention at the present time. Various modifications, additions and alternative designs will become, of course, apparent to those skilled in the art in light of the foregoing teachings without departing from the spirit and scope of the disclosed invention. Thus, it should be appreciated that the present invention is not limited to the disclosed embodiments but may be practiced within the full scope of the appended claims.

This application is based upon and claims the benefit of priority from the prior Japanese Patent Application No. 2013-058370, filed Mar. 21, 2013, the entire contents of which are incorporated herein by reference.

What is claimed is:

1. A light-emitting device comprising a GaN-based semiconductor,
the light-emitting device having a structure in which an n-type semiconductor layer, a superlattice structure layer including at least one InGaN superlattice layer, an active layer, an AlGaN-based semiconductor layer, and a p-type semiconductor layer are sequentially deposited in that order, wherein
a concavo-convex structure is formed on an interface of the AlGaN-based semiconductor layer with the p-type semiconductor layer;
the active layer is an InGaN layer or an InGaN quantum well layer; and
the InGaN superlattice layer has an In composition that is greater than an In composition of the active layer.

2. The light-emitting device according to claim 1, wherein the InGaN superlattice layer is an InₓGa₁₋ₓN layer (x is an In composition); the AlGaN-based semiconductor layer is an Al_{y}Ga_{1-y}N layer (y is an Al composition); and the In composition (x) and the Al composition (y) satisfy the following relations: 0.37≦x≦0.45, 0.14≦y≦0.24, and x×y≦0.09.

3. The light-emitting device according to claim 2, wherein the In composition (x) and the Al composition (y) satisfy the following relation: 0.06≦x×y≦0.09.
